(19) United States
(12) Patent Application Publication
(10) Pub. No.: US 2025/0003066 A1
(43) Pub. Date: Jan. 2, 2025

(54) SUBSTRATE PROCESSING APPARATUS, GAS NOZZLE, METHOD OF PROCESSING SUBSTRATE, AND METHOD OF MANUFACTURING SEMICONDUCTOR DEVICE

(71) Applicant: Kokusai Electric Corporation, Tokyo (JP)

(72) Inventors: Yusaku OKAJIMA, Toyama-shi (JP); Mika URUSHIHARA, Toyama-shi (JP)

(73) Assignee: Kokusai Electric Corporation, Tokyo (JP)

(21) Appl. No.: 18/886,407

(22) Filed: Sep. 16, 2024

Related U.S. Application Data
(63) Continuation of application No. PCT/JP2022/012207, filed on Mar. 17, 2022.

(51) Int. Cl. C23C 16/455

(52) U.S. Cl. CPC C23C 16/4551; C23C 16/45557

(57) ABSTRACT

There is provided a technique including a process chamber in which a substrate is processed, and a gas supplier including a first ejection port that ejects a first gas on an upper position in a direction perpendicular to a surface of the substrate and a second ejection port that ejects a second gas on a lower position in the direction.

### CROSS-REFERENCE TO RELATED APPLICATION

This application is a Bypass Continuation Application of PCT International Application No. PCT/JP2022/012207, filed on Mar. 17, 2022, the entire contents of which are incorporated herein by reference.

### BACKGROUND

The present disclosure relates to a substrate processing apparatus, a gas nozzle, a method of processing a substrate, and a method of manufacturing a semiconductor device.

### DESCRIPTION OF THE RELATED ART

As one aspect of a substrate processing apparatus used in a process of manufacturing a semiconductor device, for example, a substrate processing apparatus that collectively processes a plurality of substrates is used.

### SUMMARY

There is provided a technique that enables to perform in-plane uniform processing on a substrate to be processed.

In order to solve the problem described above, in one embodiment of the present disclosure,

there is provided a technique including:

a process chamber in which a substrate is processed; and

a gas supplier including a first ejection port that ejects a first gas on an upper position in a direction perpendicular to a surface of the substrate and a second ejection port that ejects a second gas on a lower side position in the direction.

### BRIEF DESCRIPTION OF THE DRAWINGS

FIG. 1 is an explanatory view illustrating a schematic configuration example of a substrate processing apparatus according to one aspect of the present disclosure.

FIG. 2 is an explanatory view illustrating a schematic configuration example of the substrate processing apparatus according to one aspect of the present disclosure.

FIG. 3 is an explanatory view illustrating a schematic configuration example of the substrate processing apparatus according to one aspect of the present disclosure.

FIG. 4 is an explanatory view for explaining a substrate support according to one aspect of the present disclosure.

FIGS. 5A and 5B are explanatory diagrams for explaining a gas supply system according to one aspect of the present disclosure.

FIG. 6 is an explanatory diagram for explaining a gas exhaust system according to one aspect of the present disclosure.

FIGS. 7A to 7C are explanatory diagrams for explaining a gas usable in one aspect of the present disclosure.

FIG. 8 is an explanatory diagram for explaining a controller of the substrate processing apparatus according to one aspect of the present disclosure.

FIGS. 9A to 9D are explanatory views illustrating a schematic configuration example of a gas nozzle according to one aspect of the present disclosure.

FIG. 10 is a flowchart for explaining a substrate processing flow according to one aspect of the present disclosure.

FIGS. 11A and 11B are explanatory diagrams illustrating exemplary gas supply from the gas nozzle according to one aspect of the present disclosure.

FIG. 12 is an explanatory diagram illustrating exemplary gas supply from the gas nozzle according to one aspect of the present disclosure.

### DETAILED DESCRIPTION

Hereinafter, embodiments of the present aspect will be described with reference to the drawings. The drawings used in the following descriptions are all schematic, and dimensional relationships of elements, ratios of the elements, and the like in the drawings do not necessarily coincide with actual ones. In addition, for example, a plurality of drawings does not necessarily coincide with each other in the dimensional relationship between each element or in the ratio between each element.

### (1) Configuration of Substrate Processing Apparatus

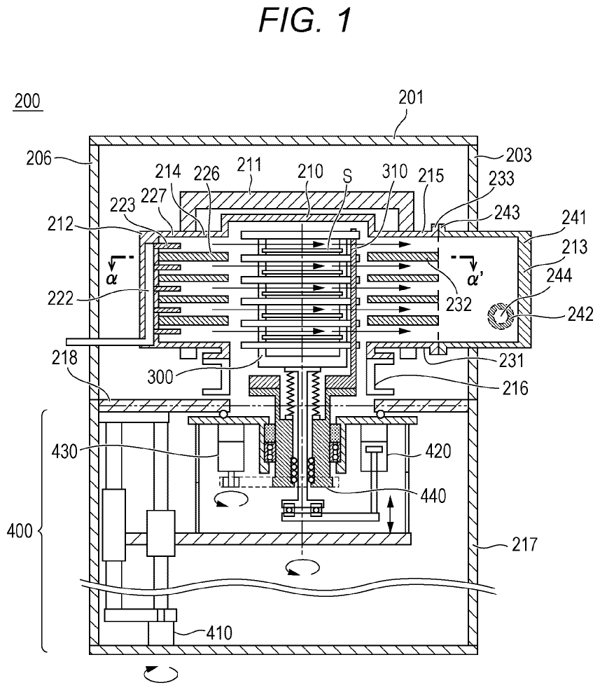

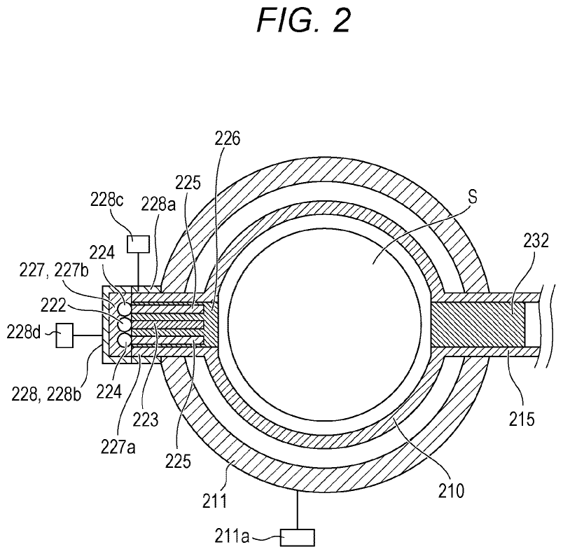

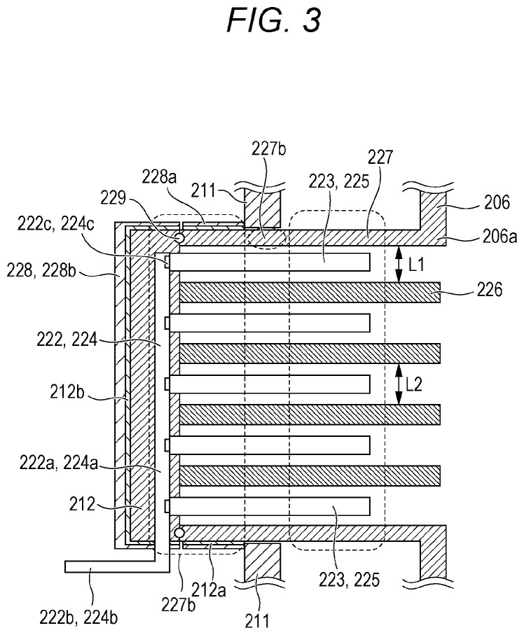

A schematic configuration of a substrate processing apparatus according to one aspect of the present disclosure will be described with reference to FIGS. 1 to 8. FIG. 1 is a side sectional view of a substrate processing apparatus 200, and FIG. 2 is a cross-sectional view taken along line α-α′ in FIG. 1. For convenience of explanation, a nozzle 223 and a nozzle 225 are added here. FIG. 3 is an explanatory view for explaining a relationship between a housing 227, a heater 211, and a distributor. For convenience of explanation, a distributor 222 and the nozzle 223 are described, and a distributor 224 and the nozzle 225 are omitted here.

Next, specific details will be described. The substrate processing apparatus 200 includes a housing 201, and the housing 201 includes a reaction tube storage chamber 206 and a transfer chamber 217. The reaction tube storage chamber 206 is disposed above the transfer chamber 217.

The reaction tube storage chamber 206 includes a reaction tube 210 in a cylindrical shape extending in the vertical direction, the heater 211 serving as a heater (furnace body) installed on the outer periphery of the reaction tube 210, a gas supply structure 212 serving as a gas supplier, and a gas exhaust structure 213 serving as a gas exhauster. Here, the reaction tube 210 is also referred to as a process chamber, and the space inside the reaction tube 210 is also referred to as a processing space. The reaction tube 210 may store a substrate support 300 to be described later.

In the heater 211, a resistance heater is provided on an inner surface facing the side of the reaction tube 210, and a heat insulator is provided to surround the resistance heater. Thus, the outer side of the heater 211, that is, the side not facing the reaction tube 210 is configured to have less thermal influence. A heater controller 211a is electrically coupled to the resistance heater of the heater 211. With the heater controller 211a controlled, on/off of the heater 211 and a heating temperature may be controlled. The heater 211 is capable of heating a gas to be described later to a temperature at which the gas may be thermally decomposed. The heater 211 is also referred to as a process chamber heater or a first heater.

The reaction tube 210, an upstream side gas guide 214, and a downstream side gas guide 215 are provided inside the reaction tube storage chamber 206. The gas supplier may include the upstream side gas guide 214. In addition, the gas exhauster may include the downstream side gas guide 215.

The gas supply structure 212 is provided upstream in the gas flow direction of the reaction tube 210, and the gas is supplied from the gas supply structure 212 to the reaction tube 210. The gas exhaust structure 213 is provided downstream in the gas flow direction of the reaction tube 210, and the gas inside the reaction tube 210 is discharged from the gas exhaust structure 213.

The upstream side gas guide 214 that guides the flow of the gas supplied from the gas supply structure 212 is provided between the reaction tube 210 and the gas supply structure 212. That is, the gas supply structure 212 is adjacent to the upstream side gas guide 214. The downstream side gas guide 215 that guides the flow of the gas discharged from the reaction tube 210 is provided between the reaction tube 210 and the gas exhaust structure 213. The reaction tube 210 has a lower end supported by a manifold 216.

The reaction tube 210, the upstream side gas guide 214, and the downstream side gas guide 215 are provided as a continuous structure, and are formed of a material such as quartz or SiC, for example. These include a heat-permeable member that allows heat radiated from the heater 211 to pass through. The heat from the heater 211 causes a substrate S and the gas to be heated.

The housing constituting the gas supply structure 212 includes metal, and a housing 227, which is a part of the upstream side gas guide 214, includes quartz or the like. The gas supply structure 212 and the housing 227 are separable, and are fixed via an O-ring 229 when being fixed. The housing 227 is coupled to a connector 206a on the lateral side of the reaction tube 210.

The housing 227 extends in a direction different from the reaction tube 210 when viewed from the side of the reaction tube 210, and is coupled to the gas supply structure 212 to be described later. The heater 211 and the housing 227 are adjacent to each other at an adjacent portion 227b between the reaction tube 210 and the gas supply structure 212. The adjacent portions are referred to as the adjacent portion 227b.

The gas supply structure 212 is provided on the rear side of the adjacent portion 227b when viewed from the reaction tube 210. The gas supply structure 212 includes a distributor 224 communicable with a gas supply pipe 261 and a distributor 222 communicable with a gas supply pipe 271, which will be described later. A plurality of nozzles 223 is provided on the downstream side of the distributor 222, and a plurality of nozzles 225 is provided on the downstream side of the distributor 224. The plurality of nozzles is arranged in the vertical direction. The distributor 222 and the nozzles 223 are illustrated in FIG. 1.

An ejection port to be described later is provided on the distal end side (side opposite to the side in communication with the distributors 222 and 224) of each of the nozzles 223 and 225. Each of the nozzles 223 and 225 supplies gas into the processing space through the ejection port on the distal end side. Each of the nozzles 223 and 225 and the ejection port in communication with those nozzles are provided in a gas nozzle to be described later.

As will be described later, since the distributor 222 enables distribution of a source gas, it is also referred to as a source gas distributor. Since the nozzles 223 supply the source gas, they are also referred to as source gas supply nozzles.

In addition, since the distributor 224 enables distribution of a reactant gas, it is also referred to as a reactant gas distributor. Since the nozzles 225 supply the reactant gas, they are also referred to as reactant gas supply nozzles.

As will be described later, a gas supply pipe 251 and the gas supply pipe 261 supply different types of gases. As illustrated in FIG. 2, the nozzle 223 and the nozzle 225 are arranged side by side. Here, in the horizontal direction, the nozzle 223 is disposed at the center of the housing 227, and the nozzles 225 are disposed on both sides thereof. The nozzles disposed on both sides will be referred to as nozzles 225a and 225b, respectively.

As illustrated in FIG. 3, the distributor 222 is provided with a plurality of blow-off holes 222c. The blow-off holes 222c are provided not to overlap each other in the vertical direction. The plurality of nozzles 223 is coupled such that the blow-off holes 222c provided in the distributor 222 communicate with the inside of the individual nozzles 223. The nozzles 223 are disposed in the vertical direction between division plates 226 to be described later or between the housing 227 and the division plate 226.

The distributor 222 includes a distribution structure 222a coupled to the nozzles 223, and an introduction pipe 222b. The introduction pipe 222b communicates with the gas supply pipe 251 of a first gas supply system 250 to be described later.

The distribution structure 222a is disposed on the rear side of the heater 211 when viewed from the reaction tube 210. Thus, the distribution structure 222a is disposed at a position not easily affected by the heater 211.

An upstream side heater 228 capable of heating at a temperature lower than that of the heater 211 is provided around the gas supply structure 212 and the housing 227. The upstream side heater 228 includes two heaters 228a and 228b. Specifically, the upstream side heater 228a is provided on the surface of the housing 227 and around the surface between the gas supply structure 212 and the adjacent portion 227b. In addition, the upstream side heater 228b is provided around the gas supply structure 212. The upstream side heater 228 is also referred to as an upstream side heater or a second heater.

Here, a low temperature indicates a temperature at which the gas supplied into the distributor 222 is not re-liquefied, for example, and is also a temperature at which a low decomposition state of the gas is maintained.

In a similar manner to the distributor 222, the distributor 224 includes a distribution structure 224a coupled to the nozzles 225, and an introduction pipe 224b. The introduction pipe 224b communicates with the gas supply pipe 261 of a second gas supply system 260 to be described later. The distributor 224 and the plurality of nozzles 225 are coupled such that holes 224c provided in the distributor 224 communicate with the inside of the individual nozzles 225. As illustrated in FIG. 2, a plurality of, for example, two distributors 224 and nozzles 225 are provided, and the gas supply pipe 261 is configured to communicate with each of them. The plurality of nozzles 225 is disposed at line-symmetric positions around the nozzle 223, for example.

As described above, with the distributor and the nozzles provided for each gas to be supplied, the gas supplied from each of the gas supply pipes is not mixed in each of the gas distributors, whereby generation of particles, which may be generated by gases being mixed in the distributor 224, may be suppressed.

At least a part of the configuration of the upstream side heater 228a is disposed in parallel with the extending direction of the nozzle 223 and the nozzle 225. At least a part of the configuration of the upstream side heater 228b is provided along the arrangement direction of the distributor 222. With this arrangement, the low temperature may be maintained even in the nozzles and in the distributors.

A heater controller 228 is electrically coupled to the upstream side heater 228. Specifically, a heater controller 228c is coupled to the upstream side heater 228a, and a heater controller 228d is coupled to the upstream side heater 228b. By controlling the heater controllers 228c and 228d, it becomes possible to control on/off of the heater 228 and a heating temperature. Although the two heater controllers 228c and 228d have been described here, it is not limited thereto, and one heater controller or three or more heater controllers may be used as long as desired temperature control is enabled. The upstream side heater 228 is also referred to as a second heater.

The upstream side heater 228 is detachable, and may be detached in advance from the gas supply structure 212 and the housing 227 when the gas supply structure 212 and the housing 227 are separated. Furthermore, it may be fixed to each part, and while is it fixed to the gas supply structure 212 or the housing 227, the gas supply structure 212 and the housing 227 may be separated at the time of separating the gas supply structure 212 and the housing 227.

A metal cover 212a made of, for example, metal, which serves as a cover, may be provided between the upstream side heater 228a and the housing 227. With the metal cover 212a provided, heat generated by the upstream side heater 228a may be efficiently supplied into the housing 227. In particular, while there is concern about heat dissipation in the housing 227 due to its material of quartz, the heat dissipation may be suppressed by the metal cover 212a being provided. Accordingly, it is not needed to perform excessive heating, whereby the power supply to the heater 228 may be suppressed.

A metal cover 212b may be provided between the upstream side heater 228b and the housing constituting the gas supply structure 212. With the metal cover 212b provided, heat generated by the upstream side heater 228b may be efficiently supplied to the distributor. Accordingly, the power supply to the upstream side heater 228 may be suppressed.

The upstream side gas guide 214 includes the housing 227 and the division plates 226. A part of the division plate 226 serving as a partition facing the substrate S is extended in the horizontal direction to be larger than at least the diameter of the substrate S. The horizontal direction mentioned here indicates a side wall direction of the housing 227. A plurality of the division plates 226 is disposed in the vertical direction in the housing 227. The division plate 226 is fixed to the side wall of the housing 227, and is configured such that gas is not caused to move to a lower or upper adjacent region beyond the division plate 226. Such configuration in which the gas is not caused to move beyond enables reliable formation of a gas flow to be described later.

The division plates 226 have a continuous structure without a hole. Each of the division plates 226 is provided at a position corresponding to the substrate S. The nozzle 223 and the nozzle 225 are provided between the division plates 226 and between the division plate 226 and the housing 227. That is, the nozzle 223 and the nozzle 225 are provided at least for each division plate 226. With such a configuration, it becomes possible to execute a process using a first gas and a second gas for each of the spaces between the division plates 226 and between the division plate 226 and the housing 227. Thus, the process may be uniformly executed between a plurality of the substrates S.

The respective distances between the division plates 226 and the nozzles 223 disposed above the division plates 226 are desirably the same. That is, the nozzle 223 and the division plate 226 or the housing 227 disposed below the nozzle 223 are disposed to have the same height. With this arrangement, the distance from the tip of the nozzle 223 to the division plate 226 may be made the same, whereby a degree of decomposition on the substrate S may be made uniform among the plurality of substrates.

The gas flow of the gas discharged from the nozzle 223 and the nozzle 225 is guided by the division plate 226, and is supplied to the surface of the substrate S. Since the division plate 226 extends in the horizontal direction and has a continuous structure without a hole, the mainstream of the gas is suppressed from moving in the vertical direction, and moves in the horizontal direction. Therefore, the pressure loss of the gas to reach each substrate S may be vertically uniformed.

In the present aspect, the diameter of the blow-off hole 222c provided in the distributor 222 is smaller than the distance between the division plates 226 or the distance between the housing 227 and the division plate 226.

The downstream side gas guide 215 is configured such that, in the state where the substrate S is supported by the substrate support 300, the ceiling becomes higher than the substrate S arranged at the uppermost position and the bottom becomes lower than the substrate S arranged at the lowermost position of the substrate support 300.

The downstream side gas guide 215 includes a housing 231 and a division plate 232. A part of the division plate 232 facing the substrate S is extended in the horizontal direction to be larger than at least the diameter of the substrate S. The horizontal direction mentioned here indicates a side wall direction of the housing 231. Furthermore, a plurality of the division plates 232 is disposed in the vertical direction. The division plate 232 is fixed to the side wall of the housing 231, and is configured such that gas is not caused to move to a lower or upper adjacent region beyond the division plate 232. Such configuration in which the gas is not caused to move beyond enables reliable formation of a gas flow to be described later. A flange 233 is provided on the side of the housing 231 in contact with the gas exhaust structure 213.

The division plates 232 have a continuous structure without a hole. Each of the division plates 232 is provided at a position corresponding to the substrate S, the position corresponding to the division plate 226. The division plate 226 and the division plate 232 corresponding to each other are desirably equivalent in height. Furthermore, the height of the substrate S and the heights of the division plate 226 and the division plate 232 are desirably aligned at the time of processing the substrate S. With such a structure, the gas supplied from each nozzle forms a flow passing on the division plate 226, the substrate S, and the division plate 232 as indicated by the arrow in the drawing. At this time, the division plate 232 has a continuous structure extending in the horizontal direction and having no hole. With such a structure, the pressure loss of the gas discharged from each substrate S may be uniformed. Thus, the gas flow of the gas passing through each substrate S is formed in the horizontal direction toward the exhaust structure 213 while the flow in the vertical direction is suppressed.

With the division plate 226 and the division plate 232 provided, the pressure loss in the vertical direction may be uniformed on the upstream side and the downstream side of each substrate S, whereby the horizontal gas flow in which the flow in the vertical direction is suppressed may be reliably formed over the division plate 226, the substrate S, and the division plate 232.

The gas exhaust structure 213 is provided on the downstream side of the downstream side gas guide 215. The gas exhaust structure 213 mainly includes a housing 241 and a gas exhaust pipe connector 242. A flange 243 is provided on the side of the downstream side gas guide 215 of the housing 241.

The gas exhaust structure 213 communicates with the space of the downstream side gas guide 215. The housing 231 and the housing 241 have a structure continuous in height. The ceiling of the housing 231 has a height equivalent to that of the ceiling of the housing 241, and the bottom of the housing 231 has a height equivalent to that of the bottom of the housing 241.

The gas having passed through the downstream side gas guide 215 is exhausted from an exhaust hole 244. At this time, since the gas exhaust structure does not include a configuration like a division plate, a gas flow including the vertical direction is formed toward the gas exhaust hole.

The transfer chamber 217 is disposed below the reaction tube 210 through the manifold 216. In the transfer chamber 217, a vacuum transfer robot (not illustrated) places (mounts) the substrate S on the substrate support (which may be simply referred to as a boat hereinafter) 300, or the vacuum transfer robot takes out the substrate S from the substrate support 300.

The transfer chamber 217 may store therein the substrate support 300, a partition plate support 310, and an up-down direction drive mechanism 400 constituting a first driver that drives the substrate support 300 and the partition plate support 310 (which are collectively called a substrate holder) in the up-down direction and in the rotational direction. FIG. 1 illustrates a state in which the substrate holder 300 is raised by the up-down direction drive mechanism 400 and is stored in the reaction tube.

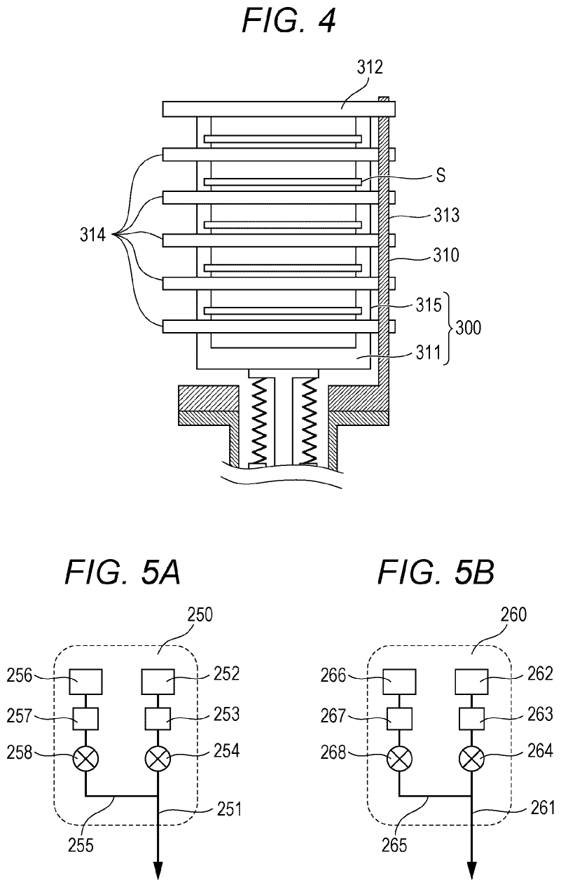

Next, details of a substrate support will be described with reference to FIGS. 1 and 4.

The substrate support includes at least the substrate support 300, and replaces, using the vacuum transfer robot, the substrate S via a substrate loading port 149 inside the transfer chamber 217, and transfers the replaced substrate S to the inside of the reaction tube 210 to form a thin film on the surface of the substrate S. The substrate support may include the partition plate support 310.

In the partition plate support 310, a plurality of disk-shaped partition plates 314 is fixed at a predetermined pitch to a column 313 supported between a base 311 and a top plate 312. The substrate support 300 is configured such that a plurality of support rods 315 is supported by the base 311, and the plurality of substrates S is supported by the plurality of support rods 315 at predetermined intervals.

The plurality of substrates S is placed on the substrate support 300 at predetermined intervals by the plurality of support rods 315 supported by the base 311. Intervals between the plurality of substrates S supported by the support rods 315 are partitioned by the disk-shaped partition plates 314 fixed (supported) to the column 313 supported by the partition plate support 310 at predetermined intervals. Here, the partition plate 314 is disposed on one or both of the upper part and the lower part of the substrate S.

The predetermined interval between the plurality of substrates S placed on the substrate support 300 is the same as the vertical interval between the partition plates 314 fixed to the partition plate support 310. The diameter of the partition plate 314 is larger than the diameter of the substrate S.

The boat 300 supports the plurality of, for example, five substrates S in multiple stages in the vertical direction with the plurality of support rods 315. The base 311 and the plurality of support rods 315 are formed of a material such as quartz or SiC, for example. Although an exemplary case where the five substrates S are supported by the boat 300 is described here, it is not limited thereto. For example, the boat 300 may be capable of supporting approximately 5 to 50 substrates S. The partition plate 314 of the partition plate support 310 is also referred to as a separator.

The partition plate support 310 and the substrate support 300 are driven by the up-down direction drive mechanism 400 in the up-down direction between the reaction tube 210 and the transfer chamber 217 and in the rotational direction around the center of the substrate S supported by the substrate support 300.

The up-down direction drive mechanism 400 constituting the first driver includes an upward/downward drive motor 410 and a rotation drive motor 430 serving as drive sources, and a boat elevator 420 including a linear actuator serving as a substrate-support lift mechanism that drives the substrate support 300 in the up-down direction.

Next, details of the gas supply system will be described with reference to FIGS. 5A and 5B.

As illustrated in FIG. 5A, the gas supply pipe 251 is provided with a first gas source 252, a mass flow controller (MFC) 253, which is a flow rate controller, and a valve 254, which is an on-off valve, in this order from the upstream direction.

The first gas source 252 is a first gas (which is also referred to as “first element-containing gas”) source containing a first element. The first gas is a source gas, that is, one of process gases. Here, the first gas is a gas in which at least two atoms of silicon (Si) are bonded and containing, for example, Si and chlorine (Cl), and is a source gas containing a Si—Si bond, such as a hexachlorodisilane (Si₂Cl₆, abbreviation: HCDS) gas illustrated in FIG. 7A. As illustrated in FIG. 7A, the HCDS gas contains Si and a chloro group (chloride) in its chemical structural formula (per molecule).

Such a Si—Si bond has a level of energy enabling decomposition due to hitting against a constituent wall of a concave portion of the substrate S to be described later inside the reaction tube 210. Here, the decomposition means that the Si—Si bond breaks. That is, the Si—Si bond hits against a wall to break. Hereinafter, the source gas containing such a Si—Si bond may be referred to as a “decomposition gas”.

The gas supply pipe 251, the MFC 253, and the valve 254 mainly constitute the first gas supply system 250 (which is also referred to as a silicon-containing gas supply system). The gas supply pipe 251 is coupled to the introduction pipe 222b of the distributor 222.

A gas supply pipe 255 is coupled to the downstream side of the valve 254 of the supply pipe 251. The gas supply pipe 255 is provided with an inert gas source 256, an MFC 257, and a valve 258, which is an on-off valve, in this order from the upstream direction. An inert gas, for example, nitrogen (N₂) gas is supplied from the inert gas source 256.

The gas supply pipe 255, the MFC 257, and the valve 258 mainly constitute a first inert gas supply system. The inert gas supplied from the inert gas source 256 acts as a purge gas for purging the gas remaining in the reaction tube 210 in the substrate processing step. The first inert gas supply system may be added to the first gas supply system 250.

As illustrated in FIG. 5B, the gas supply pipe 261 is provided with a second gas source 262, an MFC 263, which is a flow rate controller, and a valve 264, which is an on-off valve, in this order from the upstream direction. The gas supply pipe 261 is coupled to the introduction pipe 224b of the distributor 224.

The second gas source 262 is a second gas (which is also referred to as “second element-containing gas” hereinafter) source containing a second element. The second element-containing gas is one of the process gases. The second element-containing gas may be considered as a reactant gas or a modifying gas.

Here, the second element-containing gas contains the second element different from the first element. The second element is, for example, any one of oxygen (O), nitrogen (N), and carbon (C). In the present aspect, the second element-containing gas is, for example, a nitrogen-containing gas. Specifically, it is a hydrogen nitride-based gas containing an N—H bond, such as ammonia (NH₃), diazene (N₂H₂) gas, hydrazine (N₂H₄) gas, or N₃H₈ gas. Such a second gas may be hereinafter referred to as a “non-decomposition gas” in comparison with the first gas, which is a decomposition gas.

The gas supply pipe 261, the MFC 263, and the valve 264 mainly constitute the second gas supply system 260.

A gas supply pipe 265 is coupled to the downstream side of the valve 264 of the supply pipe 261. The gas supply pipe 265 is provided with an inert gas source 266, an MFC 267, and a valve 268, which is an on-off valve, in this order from the upstream direction. An inert gas, for example, nitrogen (N₂) gas is supplied from the inert gas source 266.

The gas supply pipe 265, the MFC 267, and the valve 268 mainly constitute a second inert gas supply system. The inert gas supplied from the inert gas source 266 acts as a purge gas for purging the gas remaining in the reaction tube 210 in the substrate processing step. The second inert gas supply system may be added to the second gas supply system 260.

It is desirable not to dispose an inhibitor that inhibits the flow of the supplied gas between the nozzle 223 and the nozzle 225 and the substrate S. In particular, an inhibitor is not disposed between the substrate S and the nozzle 223 that supplies the gas containing the Si—Si bond.

If a configuration for inhibiting the gas flow is provided, it is considered that the gas hits against the inhibitor so that the partial pressure increases. Then, decomposition of the gas may be excessively promoted. In this case, the gas consumption amount increases, and the amount of the undecomposed gas supplied to the concave portion decreases, and as a result, a desired step coverage may not be achieved.

In view of the above, it is desirable not to provide an obstacle for the purpose of suppressing an increase to a pressure at which decomposition is promoted. Although it is described that no obstacle is provided here, a certain degree of obstacle may be present as long as the pressure does not increase to the pressure at which decomposition is promoted.

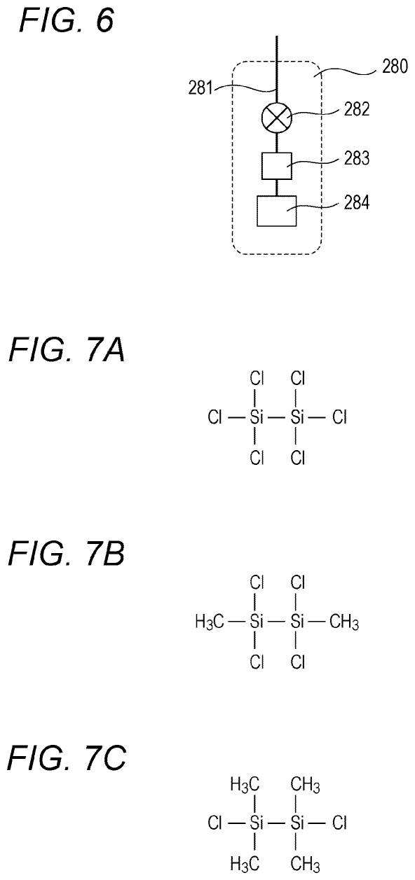

Next, an exhaust system will be described with reference to FIG. 6.

An exhaust system 280 that exhausts the atmosphere of the reaction tube 210 includes an exhaust pipe 281 communicating with the reaction tube 210, and is coupled to the housing 241 via the exhaust pipe connector 242.

As illustrated in FIG. 6, a vacuum pump 284 serving as a vacuum exhaust is coupled to the exhaust pipe 281 through a valve 282 serving as an on-off valve and an auto pressure controller (APC) valve 283 serving as a pressure regulator, whereby vacuum exhaust may be performed such that the pressure in the reaction tube 210 becomes a predetermined pressure (vacuum degree). The exhaust system 280 is also referred to as a process chamber exhaust system.

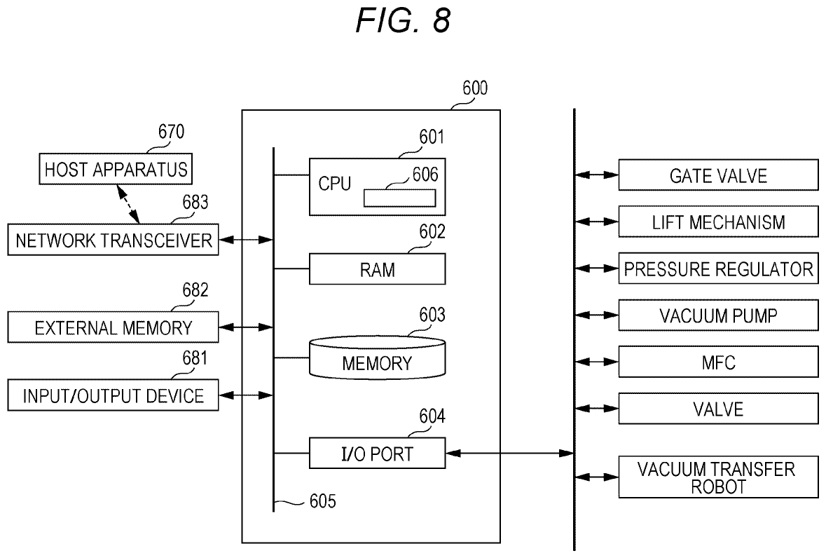

Next, a controller will be described with reference to FIG. 8. The substrate processing apparatus 200 includes a controller 600 that controls the operation of each constituent of the substrate processing apparatus 200.

FIG. 8 schematically illustrates the controller 600. The controller 600 serving as a controller is configured as a computer including a central processing unit (CPU) 601, a random access memory (RAM) 602, a memory 603 serving as a memory, and an I/O port 604. The RAM 602, the memory 603, and the I/O port 604 are capable of exchanging data with the CPU 601 via an internal bus 605. Transmission/reception of data in the substrate processing apparatus 200 is performed in accordance with an instruction from a transmission/reception instructor 606, which is one function of the CPU 601.

The controller 600 is provided with a network transceiver 683 connected to a host apparatus 670 via a network. The network transceiver 683 may receive, for example, information regarding the processing history and the processing schedule of the substrate S stored in a pod 111 from the host apparatus.

The memory 603 includes, for example, a flash memory, a hard disk drive (HDD), or the like. The memory 603 readably stores therein a control program for controlling the operation of the substrate processing apparatus, a process recipe describing procedures and conditions of the substrate processing, and the like.

The process recipe functions as a program for causing the controller 600 to perform each procedure in the substrate processing step to be described later to obtain a predetermined result. Hereinafter, the process recipe, the control program, and the like will also be collectively and simply referred to as a program. The term “program” in the present specification may include only the process recipe alone, only the control program alone, or both of them. The RAM 602 is configured as a memory area (work area) in which programs, data, and the like read by the CPU 601 are temporarily stored.

The I/O port 604 is coupled to each constituent of the substrate processing apparatus 200. The CPU 601 reads the control program from the memory 603 to execute it, and reads the process recipe from the memory 603 in response to an input of an operation command from an input/output device 681 or the like. Then, the CPU 601 may control the substrate processing apparatus 200 in accordance with the content of the read process recipe.

The CPU 601 includes the transmission/reception instructor 606. Using an external memory (e.g., magnetic disk such as a hard disk, optical disk such as a digital versatile disc (DVD), magneto-optical disk such as a magneto-optical disc (MO), or semiconductor memory such as a universal serial bus (USB) memory) 682 storing the program described above, for example, the program is installed into a computer to implement the controller 600 according to the present aspect. However, the means for supplying the program to the computer is not limited to the case of supplying the program through the external memory 682. For example, the program may be supplied using a communication means such as the Internet or a dedicated line, instead of through the external memory 682. Note that the memory 603 and the external memory 682 are configured as a computer-readable recording medium. Hereinafter, these will also be collectively and simply referred to as a recording medium. The term “recording medium” in the present specification may include only the memory 603 alone, only the external memory 682 alone, or both of them.

### (2) Configuration of Gas Nozzle

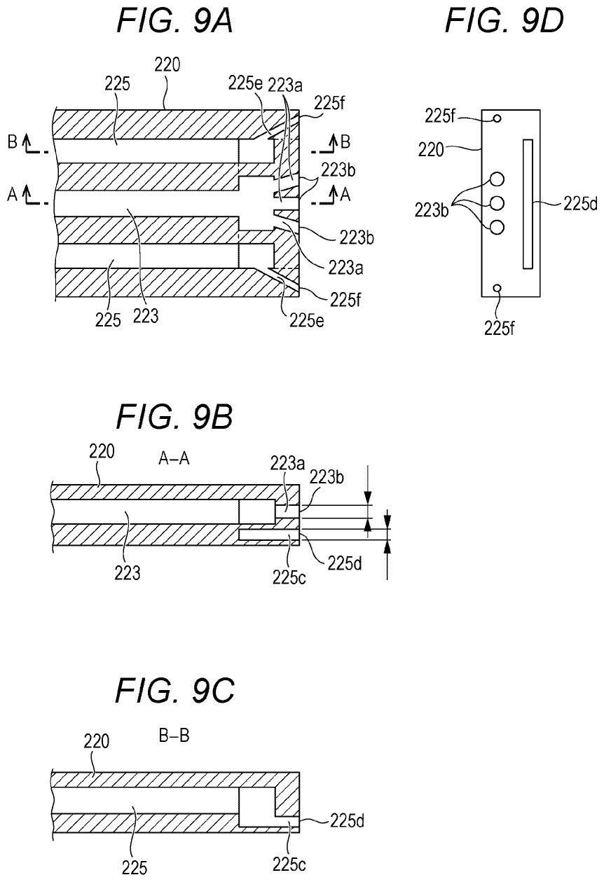

Next, a schematic configuration of the gas nozzle provided with each of the nozzles 223 and 225 and the like will be described with reference to FIGS. 9A to 9D. FIGS. 9A to 9D are explanatory views of a gas nozzle 220, and FIG. 9B illustrates a cross-sectional view taken along line A-A in FIG. 9A, FIG. 9C illustrates a cross-sectional view taken along line B-B in FIG. 9A, and FIG. 9D illustrates a side view of FIG. 9A.

A plurality of the gas nozzles 220 is disposed in the vertical direction to correspond to the plurality of substrates S supported by the substrate support 300. That is, the gas nozzles 220 are provided in multiple stages along the direction in which the substrates S are loaded, and are disposed at each position between the division plates 226 and between the division plate 226 and the housing 227.

As illustrated in FIG. 9A, each of the plurality of gas nozzles 220 is provided with the nozzle 223 and the nozzles 225 arranged on both sides thereof to be positioned side by side.

As illustrated in FIGS. 9A, 9B, and 9D, the distal end side of the nozzle 223 (side opposite to the side in communication with the distributor 222) communicates with a first ejection port 223b through a first gas branch path 223a. With this arrangement, the first gas supplied through the nozzle 223 is ejected from the first ejection port 223b toward the substrate S supported by the substrate support 300.

Furthermore, as illustrated in FIGS. 9A, 9C, and 9D, the distal end side of the nozzle 225 (side opposite to the side in communication with the distributor 224) communicates with second ejection ports 225d and 225f through second gas branch paths 225c and 225e. With this arrangement, the second gas supplied through the nozzle 225 is ejected from the second ejection ports 225d and 225f toward the substrate S supported by the substrate support 300.

The first ejection port 223b and the second ejection ports 225d and 225f are both provided on the end surface of the gas nozzle 220. Specifically, as illustrated in FIG. 9B, on the end surface of the gas nozzle 220, the first ejection port 223b is provided on the upper position in the vertical direction (i.e., direction perpendicular to the surface of the substrate S; this direction will be simply referred to as a “perpendicular direction” hereinafter), which is the stacking direction of the substrates S. On the other hand, the second ejection port 225d is provided on the lower position in the perpendicular direction. Thus, the first ejection port 223b ejects the first gas on the upper positon in the perpendicular direction, and the second ejection port 225d ejects the second gas on the lower position in the perpendicular direction. The second ejection port 225f is not necessarily provided on the lower position in the perpendicular direction.

In such a gas nozzle 220, the nozzle 223, the first gas branch path 223a, and the first ejection port 223b constitute a first gas supply flow path that supplies the first gas to the upper position in the perpendicular direction. In addition, at least the nozzle 225, the second gas branch path 225c, and the second ejection port 225d constitute a second gas supply flow path that supplies the second gas to the lower position in the perpendicular direction. The second gas supply flow path may include the second gas branch path 225e and the second ejection port 225f.

As illustrated in FIG. 9A, the first gas branch path 223a included in the first gas supply flow path is formed to branch the gas flow from the nozzle 223 into a plurality of (e.g., three) flows. With this arrangement, as illustrated in FIG. 9D, a plurality of (e.g., three) the first ejection ports 223b is provided along the direction orthogonal to the perpendicular direction (this direction will be simply referred to as a “horizontal direction” hereinafter) (i.e., to be positioned side by side).

All of the plurality of first ejection ports 223b have the same shape, and are formed in a circular shape, for example. The formation size and the like of the first ejection ports 223b will be detailed later.

At least one of those first ejection ports 223b is arranged to provide for radial injection with respect to the substrate S. The radial injection includes gas injection from the center side of the horizontal width of the gas nozzle 220 toward the edge side of the substrate S. That is, in such a manner that at least one of the first ejection ports 223b that eject the first gas faces the edge side of the substrate S from the center side of the horizontal width of the gas nozzle 220, the first gas branch path 223a that communicates with the first ejection port 223b is configured. Specifically, of the three first gas branch paths 223a positioned side by side, the paths on opposite sides are arranged to face opposite edge sides of the substrate S, whereby the first gas is radially ejected from the individual first ejection ports 223b.

On the other hand, the second gas branch path 225c included in the second gas supply flow path is formed to gather the gas flows from the respective nozzles 225 arranged on both sides of the nozzle 223 into one. With this arrangement, as illustrated in FIG. 9D, the second ejection port 225d is provided to be configured in one laterally long shape whose longitudinal direction extends in the horizontal direction. The formation size and the like of the second ejection port 225d will be detailed later.

### (3) Procedure of Semiconductor Device Manufacturing Process

Next, a process of forming a thin film on the substrate S using the substrate processing apparatus 200 having the configuration described above will be described as one step of a semiconductor manufacturing process. In the following descriptions, the operation of each constituent included in the substrate processing apparatus is controlled by the controller 600.

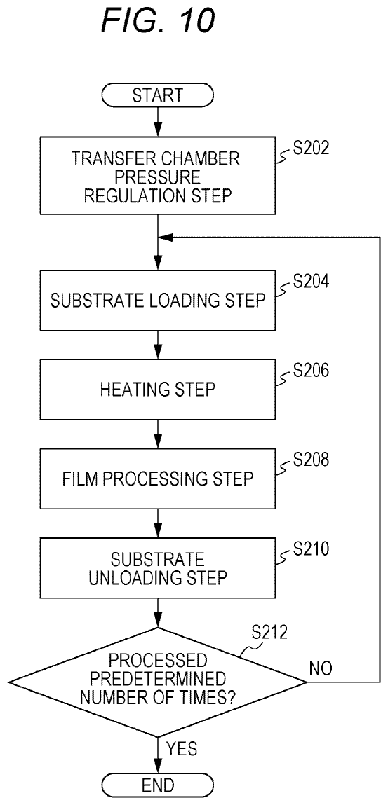

Here, a film forming process for forming a film on the substrate S by alternately supplying the first gas and the second gas will be described with reference to FIG. 10.

### (S202)

A transfer chamber pressure regulation step S202 will be described. Here, the pressure in the transfer chamber 217 is assumed to be the same level as that in a vacuum transfer chamber 140. Specifically, an exhaust system (not illustrated) coupled to the transfer chamber 217 is operated to exhaust the atmosphere in the transfer chamber 217 so that the atmosphere in the transfer chamber 217 becomes a vacuum level.

The heater 282 may be operated in parallel with this step. Specifically, each of a heater 282a and a heater 282b may be operated. When the heater 282 is operated, it is operated at least during a film processing step 208 to be described later.

### (S204)

Next, a loading step S204 will be described.

When the transfer chamber 217 reaches the vacuum level, transfer of the substrates S starts. When the substrate S arrives at the vacuum transfer chamber 140, a gate valve (not illustrated) adjacent to the substrate loading port 149 is released, and the substrate S is loaded into the transfer chamber 217 from an adjacent vacuum transfer chamber (not illustrated).

At this time, the substrate support 300 stands by in the transfer chamber 217, and the substrate S is transferred to the substrate support 300. When a predetermined number of substrates S are transferred to the substrate support 300, the vacuum transfer robot is retracted to the housing 141, and the substrate support 300 is raised to move the substrates S into the reaction tube 210.

In the movement to the reaction tube 210, the surface of the substrate S is positioned to be aligned with the height of the division plate 226 and the division plate 232.

### (S206)

A heating step S206 will be described. When the substrates S are loaded into the reaction tube 210, the inside of the reaction tube 210 is controlled to have a predetermined pressure, and the heater 211 is controlled such that the surface temperature of the substrates S becomes a predetermined temperature. The heat is added to increase the temperature to a high temperature zone to be described later, which is, for example, 400° C. or higher and 800° C. or lower. The temperature is preferably 500° C. or higher and 700° C. or lower. The pressure may be, for example, 50 to 5,000 Pa. When the upstream side heater 228 is operated at this time, control is performed such that the gas passing through the distributor 222 is heated to a temperature in a low-decomposition temperature zone to be described later or in an undecomposition temperature zone not to be subject to re-liquefaction. For example, the heat is added such that the temperature of the gas reaches approximately 300° C.

### (S208)

The film processing step S208 will be described. The film processing step S208 is performed after the heating step S206. In the film processing step S208, according to the process recipe, the first gas supply system 250 is controlled to supply the first gas into the reaction tube 210, the second gas supply system 260 is controlled to supply the second gas into the reaction tube 210, and the exhaust system 280 is further controlled to exhaust the process gas from the reaction tube 210, thereby performing the film processing. Although a chemical vapor deposition (CVD) processing is performed while the first gas and the second gas are simultaneously present in the processing space here, the first gas and the second gas may be alternately supplied into the reaction tube 210 to perform an alternate supply processing. Furthermore, when the second gas is processed as a plasma state, it may be processed into the plasma state using a plasma generator (not illustrated).

The following method is conceivable as the alternate supply processing, which is a specific example of the film processing method. For example, the first gas is supplied into the reaction tube 210 in a first step, the second gas is supplied into the reaction tube 210 in a second step, an inert gas is supplied into the reaction tube 210 and the atmosphere in the reaction tube 210 is exhausted as a purge step between the first step and the second step, and the alternate supply processing is performed in which a combination of the first step, the purge step, and the second step is performed a plurality of times, thereby forming a desired film.

A gas flow of the supplied gas is formed in the upstream side gas guide 214, the space above the substrate S, and the downstream side gas guide 215. At this time, since the gas is supplied to the individual substrates S in a state where there is no pressure loss on the substrates S, uniform processing may be performed among the substrates S.

### (S210)

A substrate unloading step S210 will be described. In S210, the processed substrates S are unloaded outward from the transfer chamber 217 in a reverse procedure to the substrate loading step S204 described above.

### (S212)

Determination S212 will be described. Here, it is determined whether the substrate has been processed a predetermined number of times. When it is determined that the processing has not been performed the predetermined number of times, the process returns to the loading step S204, and the next substrate S is processed. When it is determined that the processing has been performed the predetermined number of times, the process is terminated.

While the formation of the horizontal gas flow has been described above, it is sufficient if the mainstream of the gas is formed in the horizontal direction as a whole, and the gas flow may be diffused in the vertical direction as long as the uniform processing of the plurality of substrates is not affected.

In addition, it is needless to say that the expressions of the same level, equivalent, equal, and the like in the descriptions above include substantially the same meaning.

### (4) Mode of Gas Supply

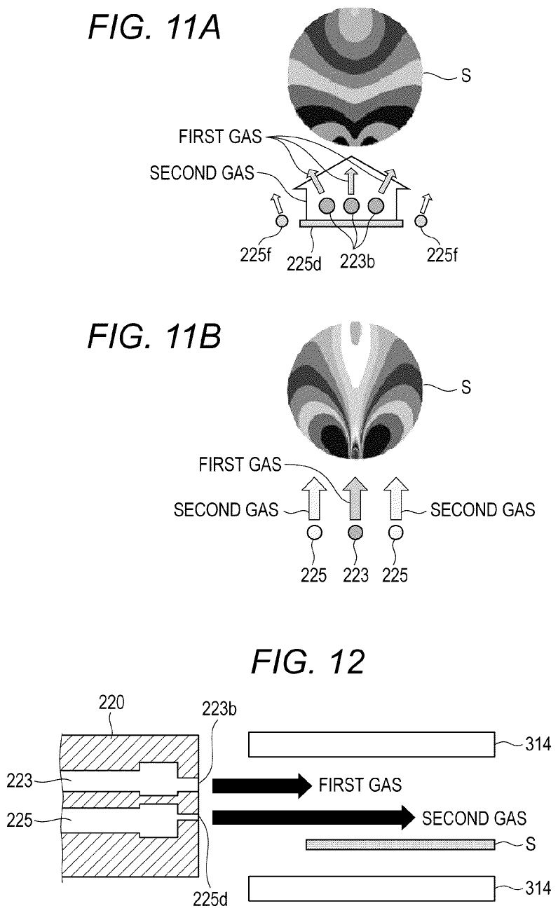

Next, a specific aspect of the gas supply in the film processing step S208 will be described with reference to FIGS. 11A to 12. In the film processing step S208, for example, the first gas and the second gas are supplied to the reaction tube storage chamber 206.

The first gas and the second gas are supplied in the horizontal direction with respect to the substrate S (i.e., along the in-plane direction of the substrate S). In that case, as illustrated in FIG. 11B, for example, when the first gas and the second gas are supplied from the nozzle 223 and the nozzles 225 toward the substrate S, a large vortex is generated on the surface of the substrate S so that the residence time of the first gas, which is a decomposition gas, becomes longer due to the flow of the vortex, whereby the decomposition may proceed to cause a film formation failure. Furthermore, unevenness may occur in the in-plane film formation state due to the respective gases passing over the substrate S without being mixed, or a gap space between the nozzles 223 and 225 may be formed so that the gas stays in the gap space, which may result in a film formation failure. That is, when the first gas, which is a decomposition gas, and the second gas, which is a non-decomposition gas, are hardly mixed on the surface of the substrate S, it becomes difficult to control the in-plane unevenness.

On the other hand, according to the gas nozzle 220 configured as described above, the first gas is supplied from the nozzle 223 to the substrate S on the upper positon in the perpendicular direction through the first gas branch path 223a and the first ejection port 223b, as illustrated in FIG. 12. In addition, the second gas is supplied from the nozzle 225 to the substrate S on the lower position in the perpendicular direction through at least the second gas branch path 225c and the second ejection port 225d. Therefore, the first gas, which is a decomposition gas, and the second gas, which is a non-decomposition gas, may be simultaneously supplied to the substrate S from different gas flow paths.

Moreover, the gas nozzle 220 is configured such that, at the time of supplying the first gas and the second gas, the flow velocity of the second gas from the second ejection port 225d becomes higher than the flow velocity of the first gas from the first ejection port 223b. The flow velocity of the first gas is mainly determined on the basis of the flow rate of the first gas flowing through the nozzle 223 and the cross-sectional areas of the first gas branch path 223a and the first ejection port 223b through which the first gas passes. In addition, the flow velocity of the second gas is mainly determined on the basis of the flow rate of the second gas flowing through the nozzle 225 and the cross-sectional areas of the second gas branch path 225c and the second ejection port 225d through which the second gas passes. That is, in the gas nozzle 220, the shapes, sizes, and the like of the first ejection port 223b and the second ejection port 225d are configured such that the flow velocity of the second gas becomes higher than the flow velocity of the first gas.

By supplying the first gas and the second gas from the gas nozzle 220 having such a configuration, as illustrated in FIG. 11A, it becomes possible to create a faster flow with the second gas so that the first gas may be caused to flow using the created flow. Thus, it becomes possible to suppress the generation of the vortex on the surface of the substrate S, and to uniformly supply the first gas with suppressed decomposition into the plane of the substrate, which is very useful for suppressing a film formation failure.

More specifically, in the gas nozzle 220, the second ejection port 225d for ejecting the second gas, which is a non-decomposition gas, has a wide laterally long shape parallel to the surface of the substrate S, and the flow of the second gas is formed along the surface of the substrate S. Then, the first gas is ejected from the first ejection port 223b located on the upper position in the perpendicular direction with respect to the second ejection port 225d, whereby the first gas is caused to uniformly flow in the plane of the substrate S following the flow of the second gas. Such a gas flow may be easily achieved by the lateral width of the second ejection port 225d in the horizontal direction (i.e., direction orthogonal to the perpendicular direction) being configured to be wider than the horizontal width of the first ejection port 223b. With this arrangement, unevenness does not occur in the in-plane film formation state of the substrate S, and the gas does not stay in the gap space between the nozzles 223 and 225, whereby it is very useful for suppressing the film formation failure while satisfactorily performing the in-plane unevenness control.

Hereinafter, details of the gas supply from the gas nozzle 220 will be described with specific examples.

### Flow Velocity

As described above, at the time of supplying the first gas and the second gas, the flow velocity of the second gas is made higher than the flow velocity of the first gas.

Specifically, for example, the flow velocity of the first gas may be 100 mm to 1 m/sec, and the flow velocity of the second gas may be 300 mm to 5 m/sec, which is higher than the flow velocity of the first gas. When at least one of the respective flow velocities is lower than the lower limit value exemplified here, decomposition of the decomposition gas proceeds, which may deteriorate the step coverage. On the other hand, when at least one of the respective flow velocities exceeds the upper limit value exemplified here, the excessively high flow velocity may lower the film formation rate.

Therefore, it is preferable that the flow velocity of the second gas is made higher than that of the first gas, and each of the flow velocities of the first gas and the second gas is within the range described above.

### (Vertical Width Shape of Ejection Port)

In order to make the flow velocity of the second gas higher than the flow velocity of the first gas, for example, it is conceivable to make the vertical width of the first ejection port 223b wider than the vertical width of the second ejection port 225d.

Specifically, for example, the vertical width of the first ejection port 223b that ejects the first gas may be 3 mm to 20 mm, and the vertical width of the second ejection port 225d that ejects the second gas may be 0.5 mm to 10 mm, which is narrower than the vertical width of the first ejection port 223b. When at least one of the respective vertical widths is narrower than the lower limit value exemplified here, the nozzle internal pressure increases, which may cause particles. On the other hand, when at least one of the respective vertical widths exceeds the upper limit value exemplified here, the lowered flow velocity may promote the decomposition of the gas.

Therefore, it is preferable that each of the vertical widths of the first ejection port 223b and the second ejection port 225d is within the range described above.

### (Volume of Gas Branch Path)

In order to make the flow velocity of the second gas higher than the flow velocity of the first gas, for example, it is conceivable to make the volume of the first gas branch path 223a larger than the volume of the second gas branch path 225c.

Specifically, for example, the volume of the first gas branch path 223a through which the first gas passes may be 100 mm² to 1,000 mm², and the volume of the second gas branch path 225c through which the second gas passes may be 50 mm² to 2,000 mm², which is smaller than the volume of the first gas branch path 223a. When at least one of the respective volumes is smaller than the lower limit value exemplified here, the nozzle internal pressure decreases, whereby the gas may not flow. On the other hand, when at least one of the respective volumes exceeds the upper limit value exemplified here, the nozzle internal pressure increases, which may cause particles.

Therefore, it is preferable that each of the volumes of the first gas branch path 223a and the second gas branch path 225c is within the range described above.

### (Nozzle Internal Pressure)

In order to make the flow velocity of the second gas higher than the flow velocity of the first gas, for example, it is conceivable to make the pressure in the first gas supply flow path including the first gas branch path 223a and the first ejection port 223b lower than the pressure in the second gas supply flow path including the second gas branch path 225c and the second ejection port 225d.

Specifically, for example, the pressure in the first gas supply flow path through which the first gas flows may be 10 Pa to 10,000 Pa, and the pressure in the second gas supply flow path through which the second gas flows may be 10 Pa to 20, 000 Pa, which is higher than the pressure in the first gas supply flow path. When at least one of the respective pressures is lower than the lower limit value exemplified here, the gas pressure with respect to the inside of the furnace decreases, whereby the gas may not flow. On the other hand, when at least one of the respective pressures exceeds the upper limit value exemplified here, the gas pressure with respect to the inside of the furnace increases, which may cause particles.

Therefore, it is preferable that each of the pressures in the first gas supply flow path and the second gas supply flow path is within the range described above.

### (Total Horizontal Width of Ejection Port)

In order to make the flow velocity of the second gas higher than the flow velocity of the first gas when a plurality of the first ejection port 223b is provided in the horizontal direction and a plurality of the second ejection ports 225d and 225f is provided in the horizontal direction, for example, it is conceivable to make the total horizontal width of the first ejection ports 223b narrower than the total horizontal width of the second ejection ports 225d and 225f.

Specifically, for example, the total horizontal width of the first ejection ports 223b may be 3 mm to 100 mm, and the total horizontal width of the second ejection ports 225d and 225f may be 10 mm to 200 mm, which is wider than the total horizontal width of the first ejection port 223b. When at least one of the respective total widths is narrower than the lower limit value exemplified here, the ejected gas flows only at the center of the substrate S, which may increase the in-plane concave tendency of the film formation. On the other hand, when at least one of the respective total widths exceeds the upper limit value exemplified here, the notch width of the heater increases, which may cause heat dissipation.

Therefore, it is preferable that each of the total horizontal widths of the first ejection ports 223b and the second ejection ports 225d and 225f is within the range described above.

### (Radial Injection)

When the total horizontal width of the first ejection ports 223b is narrower than the total horizontal width of the second ejection ports 225d and 225f, the width of the region where the first gas ejected from the first ejection ports 223b flows may be narrower than the width of the region where the second gas flows depending on the arrangement of the first ejection ports 223b. However, even in that case, the width of the region where the first gas flows may be widened if at least one of the first ejection ports 223b is arranged to provide for radial injection with respect to the substrate S. Therefore, it becomes possible to uniformly supply the first gas to the entire in-plane region of the substrate S, which is very useful for suppressing the film formation failure.

The radial injection with respect to the substrate S is performed not only by the first ejection port 223b but also by the second ejection port 225f. In that case, the second gas may be uniformly supplied to the entire region in the furnace. Moreover, when the second ejection port 225f that provides for the radial injection is provided in addition to the second ejection port 225d, it is very useful for suppressing the generation of the vortex on the surface of the substrate S.

### (Multi-Stage Arrangement)

The gas nozzles 220 that supply gas as described above are provided in multiple stages in the stacking direction of the plurality of substrates S. Therefore, the gas nozzles 220 provided in multiple stages are individually performed for each of the plurality of substrates S. Each individual gas supply enables uniform film formation in the plane of the substrate S.

### (5) Effects of Embodiments

According to the present embodiments, one or more effects to be described below are exhibited.
(a) In the present embodiments, at the time of supplying the first gas and the second gas, the first gas is ejected from the first ejection port 223b on the upper position, and the second gas is ejected from the second ejection port 225d on the lower position. In addition, the flow velocity of the second gas from the second ejection port 225d is made higher than the flow velocity of the first gas from the first ejection port 223b.

Therefore, according to the present embodiments, a flow is created by the second gas so that the first gas may flow using the created flow, whereby generation of the vortex on the surface of the substrate S may be suppressed and the first gas with suppressed decomposition may be uniformly supplied into the plane of the substrate. That is, the gas supply with respect to the substrate S is uniformed, whereby the film formation failure may be suppressed and in-plane uniform processing may be performed on the substrate S to be processed.
(b) According to the present embodiments, the vertical width of the first ejection port 223b is wider than the vertical width of the second ejection port 225d, which is preferable to make the flow velocity of the second gas higher than the flow velocity of the first gas, and is very useful for the in-plane uniform processing of the substrate S.
(c) According to the present embodiments, the volume of the first gas branch path 223a is larger than the volume of the second gas branch path 225c, which is preferable to make the flow velocity of the second gas higher than the flow velocity of the first gas, and is very useful for the in-plane uniform processing of the substrate S.
(d) According to the present embodiments, the pressure in the first gas supply flow path is lower than the pressure in the second gas supply flow path, which is preferable to make the flow velocity of the second gas higher than the flow velocity of the first gas, and is very useful for the in-plane uniform processing of the substrate S.
(e) According to the present embodiments, the horizontal width of the second ejection port 225d is wider than the horizontal width of the first ejection port 223b, which is preferable to make the flow velocity of the second gas higher than the flow velocity of the first gas, and the gas flow may be easily achieved in which the first gas is caused to uniformly flow in the plane of the substrate S following the flow of the second gas.
(f) According to the present embodiments, the first ejection port 223b has a circular shape, and the second ejection port 225d has a wide laterally long shape parallel to the surface of the substrate S, whereby the gas flow may be easily achieved in which the first gas is caused to uniformly flow in the plane of the substrate S following the flow of the second gas.
(g) According to the present embodiments, the total horizontal width (total width) of the plurality of first ejection ports 223b provided is narrower than the total horizontal width (total width) of the plurality of second ejection ports 225d and 225f, which is preferable to make the flow velocity of the second gas higher than the flow velocity of the first gas, and is very useful for the in-plane uniform processing of the substrate S.
(h) According to the present embodiments, at least one of the first ejection ports 223b is arranged to provide for radial injection with respect to the substrate S, whereby the width of the region where the first gas flows may be widened as compared with the case of not providing for the radial injection. Therefore, it becomes possible to uniformly supply the first gas to the entire in-plane region of the substrate S, which is very useful for suppressing the film formation failure.
(i) According to the present embodiments, the gas nozzles 220 are provided in multiple stages in the stacking direction of the plurality of substrates S, whereby the gas supply with respect to each of the plurality of substrates S may be individually performed, and the in-plane uniform processing may be performed on any of the plurality of substrates S.

### (6) Modified Examples, etc.

While the embodiments of the present disclosure have been specifically described above, the present disclosure is not limited to the embodiments described above, and various modifications may be made without departing from the gist of the present disclosure.

While the case where the gas nozzles 220 provided in multiple stages individually provide for the plurality of substrates S has been exemplified in the embodiments described above, the present disclosure is not limited thereto. That is, one gas nozzle 220 may be provided for each of the plurality of substrates S or for the plurality of substrates S.

While the case where the second ejection port 225d has a laterally long shape has been exemplified in the embodiments described above, the present disclosure is not limited thereto. That is, the second ejection port 225d may not have the laterally long shape, and may have a plurality of circular holes arranged in the horizontal direction, for example. Even in that case, the total horizontal width of the second ejection ports 225d is preferably wider than the total width of the first ejection ports 223b.

While the case where, in addition to the second ejection port 225d having a laterally long shape, the second ejection port 225f is provided on both sides thereof has been exemplified in the embodiments described above, the present disclosure is not limited thereto. That is, the second ejection port 225f is not necessarily provided, and when it is provided, a plurality of the second ejection ports 225f may be provided on each of both sides (i.e., four or more in total on both sides) of the second ejection port 225d.

While the case where a film is formed on the substrate S using the first gas and the second gas in the film forming process performed by the substrate processing apparatus has been exemplified in the embodiments described above, the present disclosure is not limited thereto. That is, another type of thin film may be formed using another type of gas as the process gas used for the film forming process. Furthermore, even when three or more types of process gases are used, the present disclosure may be applied as long as those process gases are supplied to perform the film forming process. Specifically, the first element may be various elements, such as titanium (Ti), silicon (Si), zirconium (Zr), or hafnium (Hf). The second element may be, for example, nitrogen (N), oxygen (O), or the like. The first element is more desirably Si as described above.

While the HCDS gas has been exemplified as the first gas here, the first gas is not limited thereto as long as it contains silicon and has a Si—Si bond, and for example, tetrachlorodimethyldisilane ((CH₃)₂Si₂Cl₄, abbreviation: TCDMDS) or dichlorotetramethyldisilane ((CH₃)₄Si₂Cl₂, abbreviation: DCTMDS) may be used. As illustrated in FIG. 7B, TCDMDS has a Si—Si bond, and further contains a chloro group and an alkylene group. As illustrated in FIG. 7C, DCTMDS has a Si—Si bond, and further contains a chloro group and an alkylene group.

While the film forming process has been exemplified as a process performed by the substrate processing apparatus in the embodiments described above, the present disclosure is not limited thereto. That is, the present disclosure may be applied to a case of performing another substrate process, such as an annealing process, a diffusion process, a oxidizing, nitriding, or a lithography process, in addition to the film forming process as long as the process is performed by supplying gas to the substrate to be processed. Furthermore, the present disclosure may also be applied to another substrate processing apparatus, such as an annealing processing apparatus, an etching apparatus, an oxidizing apparatus, a nitriding apparatus, an exposure apparatus, a coating apparatus, a drying apparatus, a heating apparatus, or a processing apparatus using plasma. Those apparatuses may be mixed in the present disclosure. Furthermore, another constituent may be added to a part of the configuration in the embodiments, or a part of the configuration in the embodiments may be deleted or replaced with another constituent.

According to one aspect of the present disclosure, it becomes possible to perform in-plane uniform processing on a substrate to be processed.

What is claimed is:

1. A substrate processing apparatus comprising:
a process chamber in which a substrate is processed; and
a gas supplier including a first ejection port that ejects a first gas on an upper position in a direction perpendicular to a surface of the substrate and a second ejection port that ejects a second gas on a lower position in the direction.

2. The substrate processing apparatus according to claim 1, wherein
a flow velocity of the second gas from the second ejection port is higher than a flow velocity of the first gas from the first ejection port.

3. The substrate processing apparatus according to claim 1, wherein
a lateral width of the second ejection port in a direction orthogonal to the perpendicular direction is wider than a lateral width of the first ejection port in the orthogonal direction.

4. The substrate processing apparatus according to claim 1, wherein
the first ejection port has a circular shape, and the second ejection port has a laterally long shape.

5. The substrate processing apparatus according to claim 1, wherein
a plurality of the first ejection ports is provided in a horizontal direction, a plurality of the second ejection ports is provided in the horizontal direction, and a total width of the first ejection ports in the horizontal direction is narrower than a total width of the second ejection ports in the horizontal direction.

6. The substrate processing apparatus according to claim 1, wherein
at least one of the first ejection ports configured to eject the first gas is arranged to provide for radial injection with respect to the substrate.

7. The substrate processing apparatus according to claim 1, further comprising
a substrate holder configured to hold a plurality of the substrates in multiple stages, wherein
the gas supplier is provided in multiple stages in a stacking direction of the plurality of substrates.

8. The substrate processing apparatus according to claim 1, further comprising:
a first gas branch path in communication with the first ejection port; and
a second gas branch path in communication with the second ejection port.

9. The substrate processing apparatus according to claim 8, wherein
a volume of the first gas branch path is larger than a volume of the second gas branch path.

10. The substrate processing apparatus according to claim 1, further comprising:
a first gas supply flow path that includes the first ejection port and supplies the first gas; and
a second gas supply flow path that includes the second ejection port and supplies the second gas.

11. The substrate processing apparatus according to claim 10, wherein
a pressure in the first gas supply flow path is lower than a pressure in the second gas supply flow path.

12. A gas nozzle comprising:
a first ejection port configured to eject a first gas on an upper position of a surface of a substrate in a perpendicular direction; and
a second ejection port configured to eject a second gas on a lower position in the perpendicular direction.

13. The gas nozzle according to claim 12, wherein
a flow velocity of the second gas from the second ejection port is higher than a flow velocity of the first gas from the first ejection port.

14. The gas nozzle according to claim 12, wherein
a lateral width of the second ejection port in a direction orthogonal to the perpendicular direction is wider than a lateral width of the first ejection port in the orthogonal direction.

15. The gas nozzle according to claim 12, wherein
the first ejection port has a circular shape, and the second ejection port has a laterally long shape.

16. The gas nozzle according to claim 12, wherein
a plurality of the first ejection ports is provided in a horizontal direction, a plurality of the second ejection ports is provided in the horizontal direction, and a total width of the first ejection ports in the horizontal direction is narrower than a total width of the second ejection ports in the horizontal direction.

17. The gas nozzle according to claim 12, wherein
at least one of the first ejection ports configured to eject the first gas is arranged to provide for radial injection with respect to the substrate.

18. A method of processing a substrate, comprising:
loading a substrate into a process chamber included in a substrate processing apparatus; and
processing the substrate by ejecting a first gas from a first ejection port provided on an upper position in a direction perpendicular to a surface of the substrate, ejecting a second gas from a second ejection port provided on a lower position in the direction, and making a flow velocity of the second gas from the second ejection port higher than a flow velocity of the first gas from the first ejection port.

19. The method of processing a substrate according to claim 18, further comprising manufacturing a semiconductor device.
